(19) United States
(12) Patent Application Publication
(10) Pub. No.: US 2020/0100400 A1
(43) Pub. Date: Mar. 26, 2020

(54) ELECTRIC INVERTER ASSEMBLY

(71) Applicant: Ford Global Technologies, LLC, Dearborn, MI (US)

(72) Inventors: Jing He, Novi, MI (US); Manfred Koberstein, Troy, MI (US); Loren John Lohmeyer, Monroe, MI (US); Mario Domonick Iaquinta, Bloomfield, MI (US)

(73) Assignee: Ford Global Technologies, LLC

(21) Appl. No.: 16/141,029

(22) Filed: Sep. 25, 2018

(51) Int. Cl. H05K 7/20; H02K 11/33; H01G 9/08; H01G 9/26; H05K 1/18; H05K 1/02; H05K 5/00; B60H 1/32

(52) U.S. Cl. CPC H05K 7/20945; H02K 11/33; H01G 9/08; H01G 9/26; H05K 2201/10015; H05K 1/0212; H05K 5/0026; B60H 1/3226; H05K 1/181

(57) ABSTRACT

An electronics assembly is provided herein. The electronics assembly includes an inverter storage unit provided in a housing. An electronics module supplies power to an electric motor. The electronics module is integrated with the inverter storage unit. One or more capacitors is disposed within the electronics module. A heating device is thermally coupled with and disposed externally of the one or more capacitors.

### FIELD OF THE INVENTION

The present disclosure generally relates to an electronics assembly, and more particularly, to an electronics assembly that may be within an inverter-integrated electric compressor for use in a heat pump system.

### BACKGROUND OF THE INVENTION

A heat pump is a proven solution to improve the driving range of electrified vehicles due to energy efficiency. When a heat pump system operates at low outdoor temperatures to provide heating function to an interior compartment or other components that may require heating (for example a battery pack soaked in cold environment), it may suffer from degraded performance, and loss of capacitance of the capacitors in the electric compressor may contribute to the degradation. Accordingly, it is desired to develop compressors that efficiently operate at all ambient temperatures, including low outdoor temperatures.

### SUMMARY OF THE INVENTION

According to some aspects of the present disclosure, an electronics assembly is provided herein. The electronics assembly includes an inverter storage unit provided in a housing. An electronics module supplies power to an electric motor. The electronics module is integrated with the inverter storage unit. One or more capacitors is disposed within the electronics module. A heating device is thermally coupled with and disposed externally of the one or more capacitors.

According to some aspects of the present disclosure, an electronics assembly is provided herein. The electronics assembly includes an inverter storage unit provided on a housing. An electronics module supplies power to an electric motor. The electronics module is integrated with the inverter storage unit. One or more capacitors is disposed within the electronics module and extends from a circuit board. A heating device thermally coupled with and disposed proximate an opposing side of the one or more capacitors from the circuit board.

According to some aspects of the present disclosure, an electronics assembly is provided herein. The electronics assembly includes an electric compressor and an electronics module for supplying power to an electric motor and electronics module having a first, higher voltage input and a second, lower voltage input. One or more capacitors is disposed within the electronics module. A heating device thermally is coupled with the capacitor and is disposed externally of the capacitor. The heating device is powered by the first or second voltage input.

These and other aspects, objects, and features of the present invention will be understood and appreciated by those skilled in the art upon studying the following specification, claims, and appended drawings.

### BRIEF DESCRIPTION OF THE DRAWINGS

In the drawings:

FIG. 1 is a side perspective view of an inverter-integrated electric compressor, according to some examples;

FIG. 2 is a side perspective view of an electronics module that may be within the inverter-integrated electric compressor, according to some examples;

FIG. 3 is a side perspective cut-away view of a capacitor within the electronics module, according to some examples;

FIG. 4 is a side perspective view of a plurality of capacitors disposed on a circuit board of the electronics module and a heating device disposed around a periphery of the capacitors, according to some examples;

FIG. 5 is a top view of the plurality of capacitors disposed on the circuit board of the electronics module and the heating device disposed around a periphery of the capacitors exemplarily illustrated in FIG. 4;

FIG. 6 is a side perspective view of the plurality of capacitors disposed on the circuit board of the electronics module and the heating device disposed above the capacitors, according to some examples; and

FIG. 7 is a top view of the plurality of capacitors disposed on the circuit board of the electronics module and the heating device disposed above the capacitors exemplarily illustrated in FIG. 6.

### DETAILED DESCRIPTION OF THE PREFERRED EXAMPLES

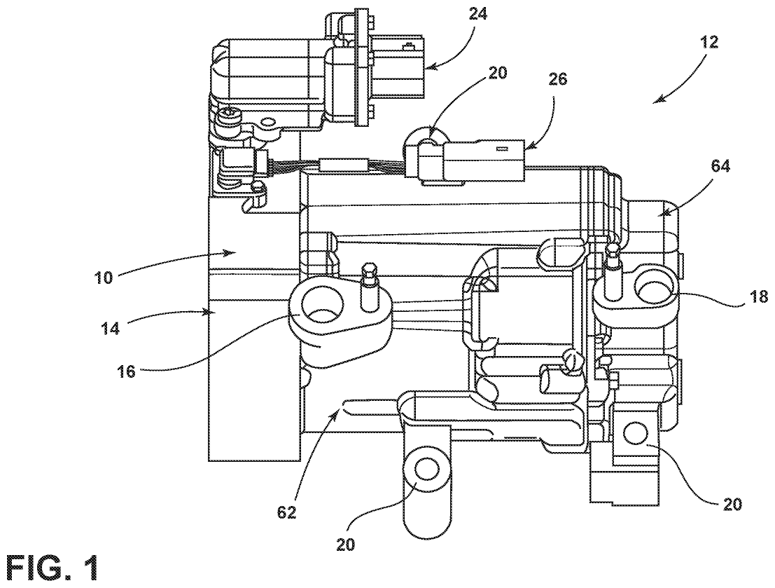

For purposes of description herein, the terms “upper,” “lower,” “right,” “left,” “rear,” “front,” “vertical,” “horizontal,” and derivatives thereof shall relate to the invention as oriented in FIG. 1. However, it is to be understood that the invention may assume various alternative orientations, except where expressly specified to the contrary. It is also to be understood that the specific devices and processes illustrated in the attached drawings, and described in the following specification are simply exemplary examples of the inventive concepts defined in the appended claims. Hence, specific dimensions and other physical characteristics relating to the examples disclosed herein are not to be considered as limiting, unless the claims expressly state otherwise.

As required, detailed examples of the present invention are disclosed herein. However, it is to be understood that the disclosed examples are merely exemplary of the invention that may be embodied in various and alternative forms. The figures are not necessarily to a detailed design and some schematics may be exaggerated or minimized to show function overview. Therefore, specific structural and functional details disclosed herein are not to be interpreted as limiting, but merely as a representative basis for teaching one skilled in the art to variously employ the present invention.

In this document, relational terms, such as first and second, top and bottom, and the like, are used solely to distinguish one entity or action from another entity or action, without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element preceded by “comprises” does not, without more constraints, preclude the existence of additional identical elements in the process, method, article, or apparatus that comprises the element.

As used herein, the term “and/or,” when used in a list of two or more items, means that any one of the listed items can be employed by itself, or any combination of two or more of the listed items can be employed. For example, if a composition is described as containing components A, B, and/or C, the composition can contain A alone; B alone; C alone; A and B in combination; A and C in combination; B and C in combination; or A, B, and C in combination.

The following disclosure describes an electronics assembly that may be configured as an inverter-integrated electric compressor. The electronics assembly includes an electronics module provided in a housing. The electronics module may include an inverter module that supplies power to an electric motor. One or more capacitors is disposed within the electronics module. A heating device is thermally coupled with the capacitor and disposed externally of the capacitor. The heating device may be activated when a temperature of the electronics module is below a threshold temperature. In some instances, the one or more capacitors may be configured as electrolytic capacitors and the heating device is configured to raise the temperature of an electrolyte material within the capacitor.

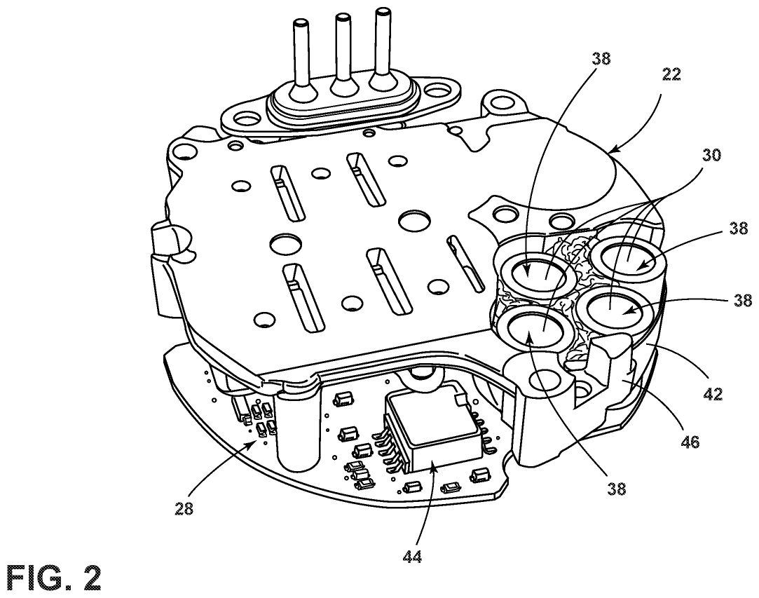

Referring to FIG. 1, an electronics assembly 10 may be configured as part of an integrated-inverter electric compressor 12 that includes an inverter housing 14 constituting an external case. The integrated-inverter electric compressor 12 may be a compressor used in a vehicle climate control system, and its driving rotation speed is controlled by an electronics module 22 (FIG. 2). The integrated-inverter electric compressor 12 may be disposed within a heat pump that may be used to provide heating and/or cooling function to maintain passenger cabin comfort.

The compressor 12 may include an electric motor assembly 62 having any type of motor therein and a compression assembly 64. The compressor 12 may be linked to the motor via a motor shaft and are thus configured so that the compression assembly 64 is driven by the electric motor assembly 62. The housing 14 may include a suction port 16. Low-temperature, low-pressure refrigerant gas taken into the housing 14 from the refrigerant suction port 16 flows around the electric motor and is then taken into and compressed by the compression assembly 64. The arrangement is such that the high-temperature, high-pressure refrigerant gas compressed by the compression assembly 64 is discharged to the outside from a discharge port 18 provided on the housing 14. The housing 14 may also be provided with attachment legs 20. The integrated-inverter electric compressor 12 is installed on a vehicle by fastening the attachment legs 20 via brackets and bolts to the vehicle. It will be appreciated that any electronics assembly 10 for any use may be made in accordance with the teachings provided herein without departing from the scope of the present disclosure.

Referring to FIGS. 1 and 2, an electronics module 22 may convert a direct current (DC) into multi-phase alternating current (AC). The DC is supplied via a first high-voltage input 24 from a power supply unit, such as a battery or the like installed in the vehicle. The electronics module 22 additionally includes a Circuit board (printed board) 28 in connection with a large number of connecting terminals. The circuit board 28 has mounted thereon a control and communication circuit having components that may be powered by a second, low-voltage input 26. A plurality of electrical components constituting the control and communication circuit, such as a controller 44, a transformer, a capacitor 30, and a coil, is provided on the circuit board 28. In some examples, the electronics module 22 may also include an optoisolator to transfer electrical signals between a low-voltage and a high-voltage circuit. The low-voltage circuit may include the controller 44, a power supply, a transceiver, and/or any other desired component. The high-voltage circuit may include a controller 44, a power supply, from the first, high-voltage input 24, one or more Insulated Gate Bipolar Junction Transistors (IGBTs) to modulate the power to the motor, and one or more capacitors 30. It will be appreciated, however, that any other component may be disposed within the electronics module 22 and within and high- or low-voltage circuit without departing from the scope of the present disclosure.

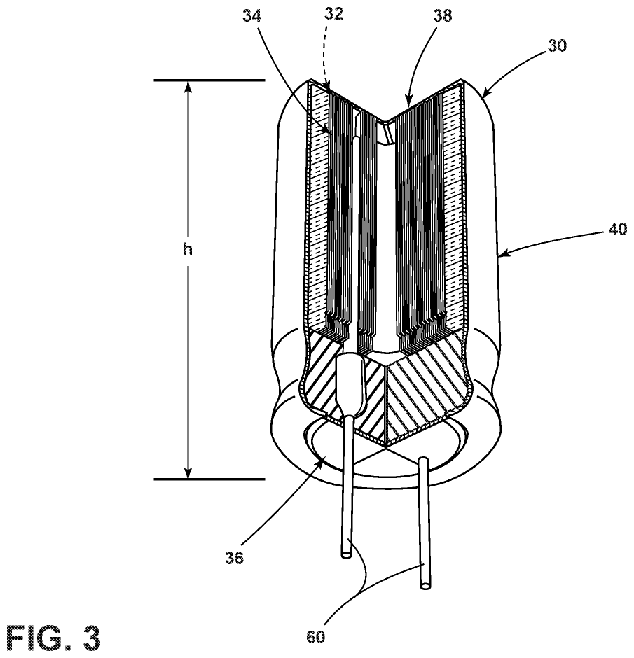

Referring to FIGS. 2 and 3, one or more DC link circuits are formed with the capacitors 30 in the electronics module 22. In some examples, electrolytic capacitors may be used, which may be small, economical, and readily available, to operate the electronics module 22 over a broad temperature range from less than −25° C. to over 120° C. An electrolytic capacitor 30 is a polarized capacitor whose anode 32 or positive plate is made of a metal that forms an insulating oxide layer through anodization. This oxide layer acts as the dielectric of the capacitor 30. A solid, liquid, or gel electrolyte 34 covers the surface of this oxide layer, serving as the (cathode) or negative plate of the capacitor 30. Due to their thin dielectric oxide layer and enlarged anode surface, electrolytic capacitors 30 may have a higher capacitance-voltage (CV) product per unit volume compared to ceramic capacitors or film capacitors, and so can have large capacitance values.

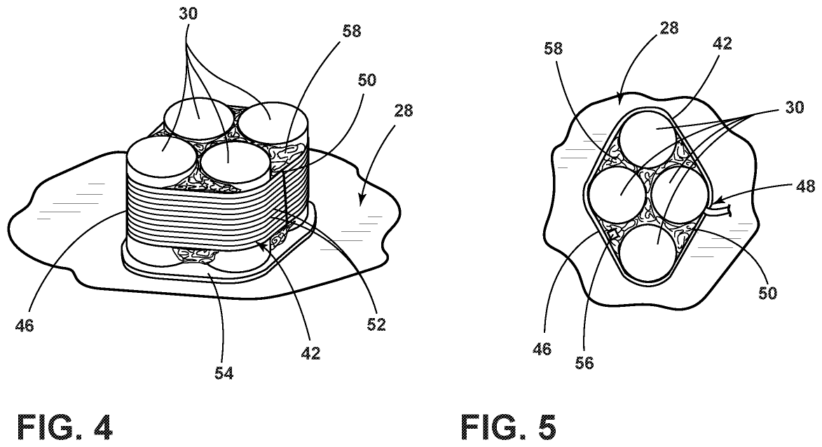

With further reference to FIGS. 3 and 4, the one or more capacitors 30 extend from the circuit board 28 with a proximal portion 36 of the one or more capacitors 30 proximate the circuit board 28 and a distal portion 38 of the one or more capacitors 30 further from the circuit board 28 than the proximal portion 36. A height h of the one or more capacitors 30 is defined by an exterior side surface 40 extending between the proximal and distal portions 36, 38 of the capacitor 30. A pair of terminals 60 (FIG. 5) extends from the proximal portion 36 of the capacitors 30.

Referring to FIGS. 3-6, a heating device 42 of any type that produces heat when activated, for example, by the controller 44 partially encompasses and/or is disposed proximately to the one or more capacitors 30. The heating device 42 is configured to heat the capacitors 30 of the electronics module 22 when the electronics assembly 10 and/or the capacitors 30 are below a threshold temperature. For example, the threshold temperature may be −10° C. in which the capacitor 30, or components thereof, may begin to freeze and/or otherwise limit operations of the electronics assembly 10. Thus, the heating device 42 may allow for operation of the electronics module 22, and consequently, the compressor 12 at temperatures below 0° C. or lower. Utilization of the compressor 12 at these temperatures may allow the heat pump to operate in a heating mode for vehicle cabin comfort and/or vehicle component thermal management (e.g., battery heating) when most inverters would otherwise be deteriorating or even unusable due to below-freezing temperatures. Accordingly, the heating device 42 disposed proximate to the capacitors 30 and/or any other component of the electronics module 22 may be heated to increase functionality and/or efficiency thereof at low ambient temperatures.

According to various examples, the heating device 42 may be configured as an ink that is coated on a film 46 by conventional screen printing, flexographic printing, or gravure printing. The wet ink thus coated on the film 46 may then be dried by heating to remove the solvent, thereby yielding a solid polymeric film with a film thickness that may be in the order of micrometers (e.g., 5-25 micrometers), according to some examples.

According to various examples, a Positive Temperature Coefficient (PTC) heating device 42 may be utilized, which refers to a material that experiences an increase in electrical resistance when its temperature rises. A PTC heating device 42 based on the polymer thick film PTC carbon compositions can be configured by many electric thermo-resistor units in parallel or in serial to have the designed heating energy density. Each thermo-resistor unit includes two electrodes 48, 50 and a printed resistive strip 52 with a resistance (R) sandwiched between two electrodes 48, 50. Upon applying a voltage (V) between the electrodes, an electric current (A) passes through the PTC resistive strip 52, yields an electric heating power output (W), following the Ohms law: that is the output Power (W)=Current (A)×Voltage (V) and the Current (A)=Voltage (V)/Resistance (R), or W=V²/R. Under an output heating power, the temperature of the heating unit is increased. Due to the PTC nature of polymer thick strip, its resistance is increased along with the increase in temperature, which causes, in turn, the decrease of output heating power. At a certain temperature, the heating power decreases to a point, which just balances the heat loss to its surrounding environment, so the temperature approaches an equilibrium and maintains constantly afterward. Thus, the PTC heating device 42 may demonstrate a self-regulating function.

An exemplary polymeric PTC ink composition may include four parts (or components), and these four parts can be functionally classified as (1) the electrically conductive component to provide electric conductivity; (2) the polymer component as the binder or adhesive to disperse the conductive component and to allow the PTC composition to be coated on a substrate; (3) the solvent to mix all components together in a liquid or gel form and allow the whole composition to be transferred onto a substrate by conventional printing methods; (4) the optional one or more additives to assist in stabilizing the ink composition and improving printability. According to various examples, a PTC ink is printed onto portions of the film 46 and then dried at high-temperature to remove the solvent thereby yielding a PTC film composing the solid parts of PTC ink, including an electrical conductor, polymer resin, and optional additives.

In other examples, the heating device 42 may be configured as a rigid and/or pliable elongated member that may include a low resistance electric conducting material being formed into an electric heating element covering an area to be heated with sufficient resistance to generate heat. In some instances, the heating device 42 is operably coupled with the low-voltage power supply of the electronics module 22. However, it will be appreciated that in some examples, the heating device 42 may additionally and/or alternatively be operably coupled with the high-power voltage.

In some examples, a thermal insulator 54 may be disposed between the circuit board 28 and the heating device 42. The thermal insulator 54 may be integrally formed with a base portion of the heating device 42 or otherwise attached to the electronics module 22 through any method. Moreover, the thermal insulator 54 may be flexible or rigid in various examples. It will be appreciated that any thermally insulating material may be used without departing from the scope of the present disclosure. It will also be appreciated that the thermal insulator 54 in some instances may consist of an air gap.

Referring again to FIGS. 4-7, a temperature sensor 56 may be operably coupled with the controller 44 and/or the heating device 42. In some examples, the temperature sensor 56 monitors the temperature of the electronics module 22 and/or the capacitors 30. In response to the capacitors 30 having a temperature below a threshold temperature, such as 0° C., the controller 44 activates the heating device 42 thereby raising the temperature of the capacitors 30. It will be appreciated that any type of temperature sensor 56 may be utilized for monitoring the temperature of the electronics module 22 and/or the capacitors 30 without departing from the teachings of the present disclosure.

With further reference to FIGS. 4-7, in addition to the heating device 42 at least partially encompassing one or more capacitors 30, a thermal transfer medium 58 may additionally be disposed within a space defined by the heating device 42 and/or between the capacitors 30. In some instances, the thermal transfer medium 58 may be configured as a fluid, paste, gel, or other medium 58 that has conformability so that it can conform to the space between the capacitors 30 and the heating device 42 and/or the space between the capacitors 30. In some instances, the thermal transfer medium 58 may assist in minimizing air gaps, which are thermally insulating. Additionally, the medium 58 is thermally conductive as well to assist in transferring heat from the heating device 42 to an exterior surface of the one or more capacitors 30.

In some examples, the medium 58 may be configured as a carrier (e.g., silicone) filled with thermally conductive particles. Due to the filler, the medium 58 may be relatively high in thermal conductivity while maintaining conformability and spreadability. Additionally and/or alternatively, due to its heat transfer characteristics and its relatively inexpensive cost, boron nitride may be used as the filler that may be coated with a hydrophobic compound. Further, carbon black may be used as a filler and is a fine particulate form of elemental carbon, which may consist of spherical particles, that in turn come together to form porous agglomerates. Carbon black may be used as a low-cost thermally conductive filler in polymer examples of the medium 58. However, it will be appreciated that any thermally conductive material may be used within the thermal transfer medium 58 without departing from the scope of the present disclosure.

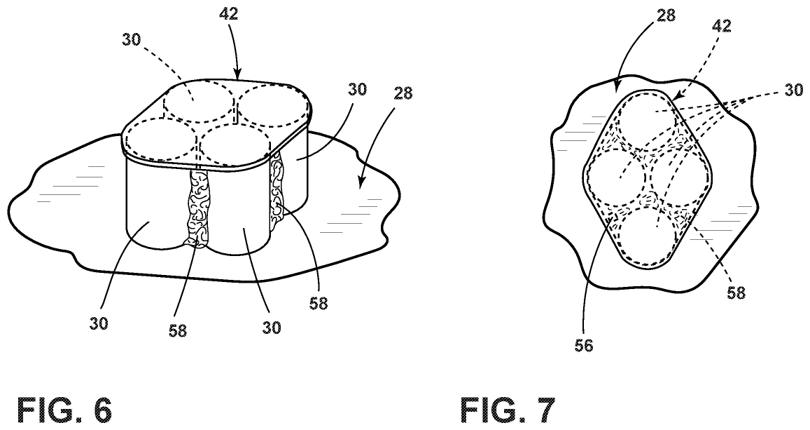

Referring to FIGS. 6 and 7, in some instances, in addition to or alternatively from the heating device 42 encompassing a periphery of the one or more capacitors 30, as exemplarily illustrated in FIGS. 4 and 5, the heating device 42 may be disposed above the distal portion 38 of the one or more capacitors 30. The heating device 42 may be operably coupled to the distal portion 38 of the one or more capacitors 30 through any method known in the art. Additionally, in some examples, the thermal transfer medium 58 may be used to maintain the position of the heating device 42 relative to the one or more capacitors 30. The thermal transfer medium 58 disposed between the heating device 42 and the distal portions 38 of the one or more capacitors 30 may be common with, or different from, the thermal transfer medium 58 disposed between the exterior side portions of the one or more capacitors 30 thereby leading to the use of a first and a second thermal transfer medium 58.

A variety of advantages may be derived from the use of the present disclosure. For example, use of the disclosed inverter-integrated compressor may be efficient and/or functional at a wide range of ambient temperatures. Moreover, the use of the heating device within the inverter may allow for use of the inverter at ambient temperatures that would otherwise make the inverter unusable. In addition to the heating device, a heat transfer medium may also be disposed between the heating device and one or more capacitors and/or within the heating device. The thermal transfer medium may be used to transfer additional heat to the one or more capacitors and/or provide additional heating to the capacitors. The inverter-integrated compressor may be manufactured at low costs when compared to other standard heat pump assemblies that operate at low temperatures, such as the integration of a PTC heating device within the climate control system to produce convection heat for the climate control system and/or systems that harvest waste heat to operate at cold temperatures.

According to various examples, an electronics assembly is provided herein. The electronics assembly includes an inverter storage unit provided in housing. An electronics module supplies power to an electric motor. The electronics module is integrated with the inverter storage unit. One or more capacitors is disposed within the electronics module. A heating device is thermally coupled with and disposed externally of the one or more capacitors. Examples of the electronics assembly can include any one or a combination of the following features:
the electronics module converts direct-current to multi-phase alternating-current;
a thermal transfer medium disposed between the one or more capacitors and the heating device;
the heating device partially encompasses the one or more capacitors;
the electronics module houses a circuit board and the one or more capacitors extend from the circuit board with a proximal portion proximate the circuit board and a distal portion further from the circuit board than the proximal portion;
a height of the one or more capacitors is defined by an exterior side surface extending between the proximal and distal portions of the capacitor;
the heating device is disposed above the distal portion of the one or more capacitors;
a thermal transfer medium is disposed between the heating device and the distal portion of the one or more capacitors;
the heating device is activated when a temperature of the electronics module is below a threshold temperature;
the temperature of the electronics module is measured by a temperature sensor within the electronics module;
the one or more capacitors are configured as electrolytic capacitors and the heating device is configured to raise a temperature of an electrolyte material within the capacitor; and/or
the electronics module and the compressor are within a vehicle climate control system.

Moreover, a method of operating an electronics assembly is provided herein. The method includes supplying power from an electronics module to an electric motor. The electronics module is integrated within an inverter storage unit provided on the housing. The method further includes heating one or more capacitors disposed within the electronics module with a heating device thermally coupled with the one or more capacitors and disposed externally of the one or more capacitors.

According to various examples, an electronics assembly is provided herein. The electronics assembly includes an electronics module for supplying power to an electric motor, the electronics module integrated within a housing. The electronics module is integrated with the inverter storage unit. One or more capacitors is disposed within the electronics module and extends from a circuit board. A heating device thermally coupled with and disposed proximate an opposing side of the one or more capacitors from the circuit board. Examples of the electronics assembly can include any one or a combination of the following features:
a thermal transfer medium disposed between the heating device and a distal portion of the one or more capacitors;
the one or more capacitors are configured as electrolytic capacitors and the heating device is configured to raise a temperature of an electrolyte material within the capacitor; and/or
the heating device is activated when a temperature of the electronics module is below a threshold temperature.

According to various examples, an electronics assembly is provided herein. The electronics assembly includes an electric compressor and an electronics module for supplying power to an electric motor and electronics module having a first, higher voltage input and a second, lower voltage input. One or more capacitors is disposed within the electronics module. A heating device thermally is coupled with the capacitor and is disposed externally of the capacitor. The heating device is powered by the first or second voltage input. Examples of the electronics assembly can include any one or a combination of the following features:
the heating device partially encompasses the one or more capacitors;
a thermal transfer medium disposed between the one or more capacitors and the heating device; and/or
the heating device is activated when a temperature of the electronics module is below a threshold temperature.

It will be understood by one having ordinary skill in the art that construction of the described invention and other components is not limited to any specific material. Other exemplary examples of the invention disclosed herein may be formed from a wide variety of materials unless described otherwise herein.

For purposes of this disclosure, the term “coupled” (in all of its forms, couple, coupling, coupled, etc.) generally means the joining of two components (electrical or mechanical) directly or indirectly to one another. Such joining may be stationary in nature or movable in nature. Such joining may be achieved with the two components (electrical or mechanical) and any additional intermediate members being integrally formed as a single unitary body with one another or with the two components. Such joining may be permanent in nature or may be removable or releasable in nature unless otherwise stated.

Furthermore, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected” or “operably coupled” to each other to achieve the desired functionality, and any two components capable of being so associated can also be viewed as being “operably couplable” to each other to achieve the desired functionality. Some examples of operably couplable include, but are not limited to, physically mateable and/or physically interacting components and/or wirelessly interactable and/or wirelessly interacting components and/or logically interacting and/or logically interactable components. Furthermore, it will be understood that a component preceding the term “of the” may be disposed at any practicable location (e.g., on, within, and/or externally disposed from the vehicle) such that the component may function in any manner described herein.

Implementations of the systems, apparatuses, devices, and methods disclosed herein may include or utilize a special-purpose or general-purpose computer including computer hardware, such as, for example, one or more processors and system memory, as discussed herein. Implementations within the scope of the present disclosure may also include physical and other computer-readable media for carrying or storing computer-executable instructions and/or data structures. Such computer-readable media can be any available media that can be accessed by a general-purpose or special-purpose computer system. Computer-readable media that store computer-executable instructions are computer storage media (devices). Computer-readable media that carry computer-executable instructions are transmission media. Thus, by way of example, and not limitation, implementations of the present disclosure can include at least two distinctly different kinds of computer-readable media: computer storage media (devices) and transmission media.

Computer storage media (devices) includes RAM, ROM, EEPROM, CD-ROM, solid state drives (“SSDs”) (e.g., based on RAM), Flash memory, phase-change memory, other types of memory, other optical disk storage, magnetic disk storage or other magnetic storage devices, or any other medium which can be used to store desired program code means in the form of computer-executable instructions or data structures and which can be accessed by a general-purpose or special-purpose computer.

An implementation of the devices, systems, and methods disclosed herein may communicate over a computer network. A “network” is defined as one or more data links that enable the transport of electronic data between computer systems and/or modules and/or other electronic devices. When information is transferred or provided over a network or another communications connection (either hardwired, wireless, or any combination of hardwired or wireless) to a computer, the computer properly views the connection as a transmission medium. Transmission media can include a network and/or data links, which can be used to carry desired program code means in the form of computer-executable instructions or data structures and which can be accessed by a general-purpose or special-purpose computer. Combinations of the above should also be included within the scope of computer-readable media.

Computer-executable instructions include, for example, instructions and data, which, when executed at a processor, cause a general-purpose computer, special-purpose computer, or special-purpose processing device to perform a certain function or group of functions. The computer-executable instructions may be, for example, binaries, intermediate format instructions such as assembly language, or even source code. Although the subject matter has been described in language specific to structural features and/or methodological acts, it is to be understood that the subject matter defined in the appended claims is not necessarily limited to the described features or acts described above. Rather, the described features and acts are disclosed as example forms of implementing the claims.

Those skilled in the art will appreciate that the present disclosure may be practiced in network computing environments with many types of computer system configurations, including an in-dash vehicle computer, personal computers, desktop computers, laptop computers, message processors, hand-held devices, multi-processor systems, microprocessor-based or programmable consumer electronics, network PCs, minicomputers, mainframe computers, mobile telephones, PDAs, tablets, pagers, routers, switches, various storage devices, and the like. The disclosure may also be practiced in distributed system environments where local and remote computer systems, which are linked (either by hardwired data links, wireless data links, or by any combination of hardwired and wireless data links) through the network, both perform tasks. In a distributed system environment, program modules may be located in both local and remote memory storage devices.

Further, where appropriate, functions described herein can be performed in one or more of: hardware, software, firmware, digital components, or analog components. For example, one or more application specific integrated circuits (ASICs) can be programmed to carry out one or more of the systems and procedures described herein. Certain terms are used throughout the description and claims to refer to particular system components. As one skilled in the art will appreciate, components may be referred to by different names. This document does not intend to distinguish between components that differ in name, but not function.

It should be noted that the sensor and/or switch examples discussed above might include computer hardware, software, firmware, or any combination thereof to perform at least a portion of their functions. For example, a sensor and/or switch may include computer code configured to be executed in one or more processors, and may include hardware logic/electrical circuitry controlled by the computer code. These example devices are provided herein for purposes of illustration, and are not intended to be limiting. Examples of the present disclosure may be implemented in further types of devices, as would be known to persons skilled in the relevant art(s).

At least some examples of the present disclosure have been directed to computer program products including such logic (e.g., in the form of software) stored on any computer usable medium. Such software, when executed in one or more data processing devices, causes a device to operate as described herein.

It is also important to note that the construction and arrangement of the elements of the invention as shown in the exemplary examples is illustrative only. Although only a few examples of the present innovations have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter recited. For example, elements shown as integrally formed may be constructed of multiple parts or elements shown as multiple parts may be integrally formed, the operation of the interfaces may be reversed or otherwise varied, the length or width of the structures and/or members or connectors or other elements of the system may be varied, the nature or number of adjustment positions provided between the elements may be varied. It should be noted that the elements and/or assemblies of the system might be constructed from any of a wide variety of materials that provide sufficient strength or durability, in any of a wide variety of colors, textures, and combinations. Accordingly, all such modifications are intended to be included within the scope of the present innovations. Other substitutions, modifications, changes, and omissions may be made in the design, operating conditions, and arrangement of the desired and other exemplary examples without departing from the spirit of the present innovations.

It will be understood that any described processes or steps within described processes may be combined with other disclosed processes or steps to form structures within the scope of the present invention. The exemplary structures and processes disclosed herein are for illustrative purposes and are not to be construed as limiting.

It is also to be understood that variations and modifications can be made on the aforementioned structures and methods without departing from the concepts of the present invention, and further it is to be understood that such concepts are intended to be covered by the following claims unless these claims by their language expressly state otherwise.

1. An inverter assembly comprising:
an inverter storage unit provided on a housing;
an electronics module for supplying power to an electric motor, the electronics module is integrated with the inverter storage unit;
a plurality of capacitors disposed within the electronics module;
a heating device thermally coupled with and disposed externally of the plurality of capacitors;
a first thermal transfer medium disposed between the heating device and at least one external side of the plurality of capacitors; and
a second thermal transfer medium disposed between each of the plurality of capacitors.

2. The inverter assembly of claim 1, wherein the electronics module also converts direct-current power to multi-phase alternating-current power.

3. The inverter assembly of claim 1, wherein
the first and second thermal transfer mediums each comprises at least one of a fluid, a paste, a gel, and a carrier, and wherein the first thermal transfer medium differs from the second transfer medium.

4. The inverter assembly of claim 1, wherein the heating device partially encompasses the plurality of capacitors.

5. The inverter assembly of claim 1, wherein the electronics module houses a circuit board and the plurality of capacitors extend from the circuit board with a proximal portion proximate the circuit board and a distal portion further from the circuit board than the proximal portion.

6. The inverter assembly of claim 5, wherein a height of the plurality of capacitors is defined by an exterior side surface extending between the proximal and distal portions of the plurality of capacitors.

7. The inverter assembly of claim 5, wherein the heating device is disposed above the distal portion of the plurality of capacitors.

8. The inverter assembly of claim 7, wherein a thermal transfer medium is disposed between the heating device and the distal portion of the plurality of capacitors.

9. The inverter assembly of claim 1, wherein the heating device is activated when a temperature of the electronics module is below a threshold temperature.

10. The inverter assembly of claim 9, wherein the temperature of the electronics module is measured by a temperature sensor within the electronics module.

11. The inverter assembly of claim 1, wherein the plurality of capacitors are configured as electrolytic capacitors and the heating device is configured to raise a temperature of an electrolyte material within the plurality of capacitors.

12. The inverter assembly of claim 1, wherein the electronics module and a compressor are within a vehicle climate control system.

13. An inverter assembly comprising:
an inverter storage unit provided on a housing;
an electronics module for supplying power to an electric motor, the electronics module integrated with the inverter storage unit;
a plurality of capacitors disposed within the electronics module and extending from a circuit board;
a heating device thermally coupled with and disposed proximate an opposing side of the plurality of capacitors from the circuit board;
a first thermal transfer medium disposed between the heating device and at least one external side of the plurality of capacitors; and
a second thermal transfer medium disposed between each of the plurality of capacitors.

14. The inverter assembly of claim 13:
wherein the first and second thermal transfer mediums each comprises at least one of a fluid, a paste, a gel, and a carrier, and wherein the first thermal transfer medium differs from the second transfer medium.

15. The inverter assembly of claim 13, wherein the plurality of capacitors are configured as electrolytic capacitors and the heating device is configured to raise a temperature of an electrolyte material within the plurality of capacitors.

16. The inverter assembly of claim 13, wherein the heating device is activated when a temperature of the electronics module is below a threshold temperature.

17. An inverter assembly comprising:
an electronics module for supplying power to an electric motor and electronics module having a first, higher voltage input and a second, lower voltage input;
a plurality of capacitors disposed within the electronics module;
a heating device thermally coupled with the plurality of capacitors and disposed externally of the plurality of capacitors, the heating device powered by the first or second voltage input;
a first thermal transfer medium disposed between the heating device and at least one external side of the plurality of capacitors; and
a second thermal transfer medium disposed between each of the plurality of capacitors.

18. The inverter assembly of claim 17, wherein the heating device partially encompasses the plurality of capacitors.

19. The inverter assembly of claim 17, further comprising:
a thermal transfer medium disposed between the plurality of capacitors and the heating device.

20. The inverter assembly of claim 17, wherein the heating device is activated when a temperature of the electronics module is below a threshold temperature.
